(19) United States
(12) Patent Application Publication
(10) Pub. No.: US 2008/0095939 A1
(43) Pub. Date: Apr. 24, 2008

(54) Method for Producing a Coat on a Piston Ring and Piston Ring

(76) Inventors: Manfred Fischer, Leichlingen (DE); Steffen Hoppe, Overath (DE)

Correspondence Address: Robert L. Stearns;Dickinson Wright PLLC, 38525 Woodward Avenue, Suite 2000, Bloomfield Hills, MI, 48304-5092, US

(21) Appl. No.: 11/571,605

(22) PCT Filed: Jun. 21, 2005
(86) PCT No.: PCT/DE05/01103

§ 371 Date: Jan. 3, 2007

(30) Foreign Application Priority Data
Jul. 3, 2004 (DE) 10 2004 032 403.4

(51) Int. Cl. C23C 16/34; B23P 15/06

(52) U.S. Cl. 427/255.394; 29/888.074

(57) ABSTRACT

The invention relates to a method for producing a coat on the outer peripheral surface of a piston ring base. According to said method, a plurality of layers is applied layer by layer to the peripheral surface by applying, using a PVD method, at least one metal adhesive layer based on Cr to the peripheral surface without adding nitrogen to the process gas. Nitrogen is added to the process gas while increasing the partial pressure of the nitrogen, thereby forming a CrN gradient layer on the adhesive layer, and finally at least one cover layer having a constant composition based on CrN, Cr₂N or a mixture of the two phases is applied to said gradient layer.

The invention concerns a procedure for the production of a coating on the external surface area of a piston ring body.

A friction-resistant overlay containing chrome and at least one chrome nitride, formed onto a carrying material, has been made known in patent filing DE-C 41 12 422 in Germany. The Nitrogen concentration of the overlay increases continually from the edge surface between the carrying material and the overlay in the direction of the outer external surface of the overlay. The overlay has one area adjacent to the outer external surface, which essentially contains a mixture of Cr₂N and CrN. Alternatively, the overlay can contain chrome. The friction-resistant overlay can be installed onto component parts which are themselves subjected to sliding friction, such as onto a piston ring or similar.

The U.S. Pat. No. 5,851,659 presents a sliding body and a process to produce such a sliding body, where the sliding body includes a layer on the basis of Cr₂N, and exhibiting a porosity of between 1.5 and 20%. The crystals of Chrome nitride are here aligned parallel to the outer surface, such that the Chrome nitride in the layers may contain CrN, Cr₂N, or a mixture of both phases.

The German patent DE-Gbm 296 95 666 presents a component element in the area of the combustion chambers, having a layering removed by a vacuum process on at least one of its surfaces, consisting of a non-metallic amorphous carbon layer whose hardened surface is graduated over the layering thickness. The layering is to be applied in a CVD-process, where the graduations are adjustable by process parameters.

Piston rings, especially those which may be installed into the first groove of the piston, are equipped among other things with wear-protection layers, as can be understood from the preceding description of the techniques, to fulfill the requirements for useful life duration. Higher cylinder pressures, direct injection, exhaust gas flow routing, and other construction features of modem engine development, as well as minimization of oil consumption, place a burden on the piston rings such that the required useful operational life requirements can no longer be guaranteed.

Given the state of technology piston ring coatings on the basis of Chrome nitride according to thin layering technology with supplemental oxygen and/or Nitrogen are understood. Such layers exhibit good solidity and combustion trace properties. Given the weardown values and the requirements to achieve for useful life, especially for high stress Diesel motors, high layer thicknesses must be produced, which are atypical for the thin layer technology. These layers are constrained by the tensions in the layering, which increase with the layer thickness, and which can lead to the formation of cracks in the layering and/or to peeling areas where the coating does not adhere. A continuity of the wear processes over time cannot be guaranteed, especially in the layering as presented in DE-C 41 12 422.

The invention here addresses the task of providing a procedure to produce a layering on the exterior surface area of a piston ring body, by means of which the piston ring layers can be produced which will serve their function for the overall useful life of the motor, in spite of the indicated motor loading. By using the Thin Layer technology, one layer should be produced which will not exhibit the disadvantages previously mentioned., and which will allow the isolation of layer thicknesses sufficient to ensure adequate functionalty characteristics throughout the entire operational life of the motor.

This assignment is satisfied by a procedure to produce a layering on the outer surface area of the piston ring body, in which multiple layers are applied onto the surface area, so that in the PVD process at least one metallic adhesive layer is applied to the surface area on the basis of Cr without the introduction of Nitrogen as a process gas, after which process gas is introduced under increasing the Nitrogen partial pressure to form a CrN-gradient layer onto the adhesive layer, and finally at least one cover layer of a constant composition on the basis of CrN, Cr₂N or a mixture of both phases is applied to the gradient layering.

Advantageous further development of the subject of this invention may be achieved from the procedural application of the sub-claims.

The assignment is also satisfied by a piston ring consisting of a body, on the outer surface of which multiple layers one above another have been applied, such that the adhesive layer faced by the outer surface area is a PVD adhesive layer on the basis of Cr, a PVD CrN adhesive layer gradient with a layer composition of Cr over Cr—Cr₂N mixture, Cr₂N—CrN mixture up to and including CrN, and on the CrN gradient layer at least one covering layer of consistent composition on the basis of CrN, Cr₂N, or a mixture of the two phases.

Advantageous further development of the subject of this invention piston ring may be reviewed on the basis of the relevant sub-claims.

The recommendation is that a layer on the basis of CrN be applied in the PVD procedure with a partially graded layering formation. The system CrN differentiates itself from the multitude of removable hard material layering systems on the basis of a relatively low self-tension. Where other layers can only be produced with a few p layer thickness before self-tensions arise and lead to layer damages, the CrN layers can be applied in significantly higher thicknesses.

At the necessary thicknesses of 30 to 50 μ for supporting long life, especially with Diesel motors, the typical layerings lead to layer-peeling or to the formation of cracks in the piston ring basic material. According to this invention the self-tensions in the CrN system are reduced at higher layer thicknesses, so that the Nitrogen content within the gradient layer will be increased in a ramping function. The invention-related layer is formed outward from the basic material of the piston ring as follows:

Basic material—Cr bond layer—CrN gradient layer—CrN covering layer

In the layering system CrN two nitrides exist alongside the metallic Cr with Cr₂N (33 Atom % N) and CrN (50 Atom % N). According to the Nitrogen partial pressure setting in the PVD process the various phases or the phase mixtures are formed.

In the layering process a metallic layer with a thickness <1 μ is isolated without the introduction of Nitrogen as a process gas. Subsequently Nitrogen is introduced as a process gas, whereby the Nitrogen partial pressure is continually increased. The layer composition within the gradient layer is then variably Cr over CrN—Cr₂N-mixture, Cr₂N, Cr₂N—CrN mixture, through to CrN. After this a cover layer of a constant composition is isolated. This can be either CrN, Cr₂N or a mixture of both phases. Surprisingly it has been shown that for overall gradient thicknesses of from 30 μ to 50 μ, 3 μ to 5 μ is sufficient to reduce the self-tension to a point where no further layer-peeling or cracks occur.

The invention object is represented by an example diagram, and is described as follows. The diagram shows:

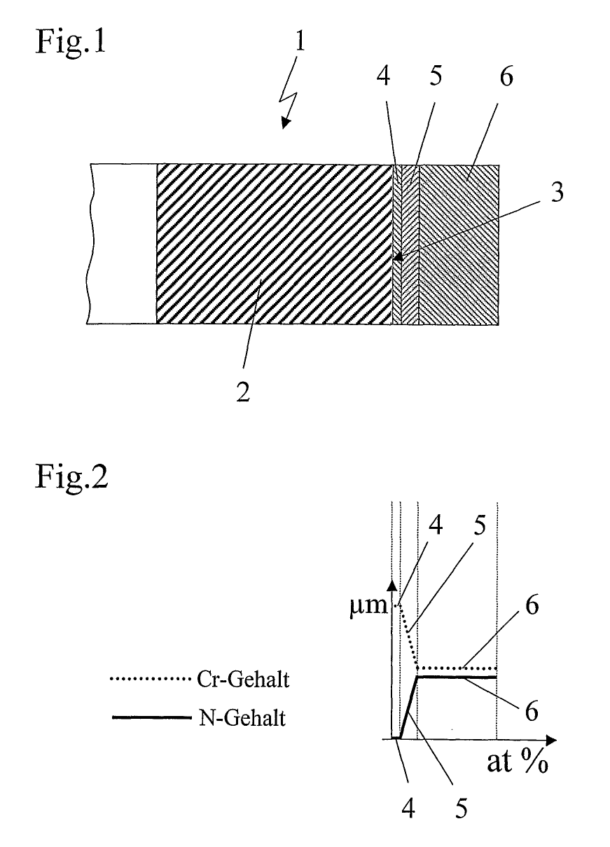

FIG. 1 Cross-section of a piston ring basic body with the operating surface layers depicted

FIG. 2 Concentration profile of Cr-N in the operating surface layers presented in FIG. 1

FIG. 1 shows the cross-section of a piston ring 1, containing a basic body 2, which has an external surface comprising the operating surface layer 3. On the external surface 3 in this example there are three layers 4, 5 and 6 laid out according to the PVD procedure. In this example layer 4 is depicted by the layer Cr, and having a layer thickness of 0.5 μ.

In the PVD procedure a CrN gradient layer 5 with a thickness of 3 μ is laid onto the layer 4. The layer composition within the CrN gradient layer 5 could be varied in such a way through the Nitrogen input as a process gas, that isolations of Cr over Cr—Cr₂N-mixture, Cr₂N, Cr₂—CrN-mixture through to CrN were available.

In the PVD procedure a cover layer 6 of consistent composition having a layer thickness of 30 μ was put on over the CrN gradient layer 5, where this layer was CrN. Cr₂N or a mixture of both phases is also an option.

In one test attempt a CrN layer having an overall thickness of 30 μ was isolated onto a piston ring 1. In one case a CR layer of 0.5 μ thickness was overlaid, in another case also a Cr layer of the same thickness and with an additional 3 μ gradient layer was overlaid. The variants having the gradient layer exhibited only as much self-tension pressure as did the layers without a gradient layer.

FIG. 2 depicts the concentration profile of the layering described in FIG. 1. The Cr and N content is indicated in Atom % as well as the layer thickness in μ. In the layering process a metallic Cr layer is first applied without Nitrogen as a process gas, ( layer 4). According to this invention the self tension levels in the Cr—N system are reduced at higher layer thicknesses, when the Nitrogen input as process gas is introduced at partial pressure with a continual increase in this example. The layer composition in the CrN gradient layer 5 is thereby varied from Cr to Cr—Cr₂N mixture, Cr₂N, Cr₂N—CrN mixture, on to CrN. After this a cover layer 6 of a constant composition is isolated, where this is CrN

1. Procedure to produce a layering on the outer surface area (3) of the piston ring body (2), in which multiple layers (4, 5, 6) are applied onto the surface area (3), so that in the PVD process at least one metallic adhesive layer (4) is applied to the surface area (3) on the basis of Cr without the introduction of Nitrogen as a process gas, after which process gas is introduced under increasing the Nitrogen partial pressure to form a CrN-gradient layer onto the adhesive layer (4), and finally at least one cover layer (6) of a constant composition on the basis of CrN, Cr₂N or a mixture of both phases is applied to the gradient layering (5)

2. Procedure according to claim 1 wherein the increasing of the Nitrogen partial pressure occurs in a type of ramping function.

3. Procedure according to claim 1 wherein the increasing of the Nitrogen partial pressure occurs continuously.

4. Procedure according to claim 1 wherein the layer composition within the CrN gradient layers (5) from Cr to Cr—Cr₂N mixture, Cr₂N, Cr₂N—CrN mixture, on to CrN.

5. Procedure according to claim 1 the wherein the adhesive layer (4) is produced with a layer thickness from 0.1 μ to 1 μ.

6. Procedure according to claim 1 wherein the CrN gradient layer (5) is produced with a layer thickness from 1 μ to 8 μ.

7. Procedure according to claim 6 the cover layer (6) is produced with a layer thickness from 10 μ to 80 μ.

8. Procedure according to claim 1 having an overall layer thickness between 30 μ and 50 μ for a CrN gradient layer (5) with a layer thickness between 2 and 6 μ and a layer (4) with a layer thickness <0/6 μ.

9. Piston ring comprising of basic body (2), onto the exterior surface area (3) of which multiple layers (4, 5, 6) are applied over one another, so that the exterior surface area (3) faced by the adhesive layer (4) is a PVD adhesive layer on the basis of Cr, on the adhesive layer (4) is a CrN-gradient layer (5) with a layer composition of Cr over Cr—Cr₂N-mixture, Cr₂N, Cr₂N—CrN-mixture on to CrN, and on the CrN gradient layer (5) at least one cover layer (6) of constant composition on the basis of CrN, Cr₂N or a mixture of both phases.

10. Piston ring according to claim 9 wherein the adhesive layer (4) exhibits a layer thickness from 0.1 μ to 1 μ.

11. Piston ring according to claim 9 wherein the CrN gradient layer (5) exhibits a layer thickness from 1 μ to 8 μ.

12. Piston ring according to claim 11 wherein the cover layer (6) exhibits a layer thickness from 10 μ to 80 μ.

13. Piston ring according to claim 9 wherein the overall layer thickness is between 30 μ and 50 μ, the adhesive layer (4) has a layer thickness <0.6 μ, and that the CrN gradient layer (5) thickness lies between 2 μ and 6 μ.
